(19) United States
(12) Patent Application Publication
(10) Pub. No.: US 2015/0027538 A1
(43) Pub. Date: Jan. 29, 2015

(54) COMPOUND SEMICONDUCTOR SOLAR BATTERY AND METHOD OF MANUFACTURING LIGHT ABSORPTION LAYER OF COMPOUND SEMICONDUCTOR SOLAR BATTERY

(71) Applicant: TDK CORPORATION, Tokyo (JP)

(72) Inventors: Yasuhiro Aida, Tokyo (JP); Daisuke Tanaka, Tokyo (JP); Masato Kurihara, Tokyo (JP)

(21) Appl. No.: 14/381,321

(22) PCT Filed: Feb. 28, 2013
(86) PCT No.: PCT/JP2013/055358

§ 371 Date: Aug. 27, 2014

(30) Foreign Application Priority Data
Mar. 2, 2012 (JP) 2012-046719

(51) Int. Cl. H01L 31/032; H01L 31/18; H01L 31/06

(52) U.S. Cl. CPC H01L 31/0322; H01L 31/06; H01L 31/18
USPC 136/262; 204/192.25; 438/95

(57) ABSTRACT

A solar battery capable of increasing conversion efficiency compared with a conventional solar battery using a chalcopyrite p-type light absorption layer. A light absorption layer of the solar battery is a p-type semiconductor layer including Cu, Ga, and an element selected from group VIb elements. A photoluminescence spectrum or a cathode luminescence spectrum obtained from the light absorption layer includes an emission peak with the half-value width of not less than 1 meV and not more than 15 meV. The ratio of the particles with the grain size of not less than 2 μm and not more than 8 μm in a surface of the light absorption layer to the surface area of the entire film is not less than 90%.

### TECHNICAL FIELD

The present invention relates to a compound semiconductor solar battery and a method of manufacturing a light absorption layer of a compound semiconductor solar battery.

### BACKGROUND ART

The development of compound semiconductor solar batteries that use a thin film semiconductor layer as a light absorption layer has progressed in recent years, replacing bulk crystal silicon solar batteries. Among others, a thin film solar battery including an absorption layer comprising a compound semiconductor layer including an element selected from group Ib of the periodic table, such as Cu, Ag, or Au; an element selected from group IIIb of the periodic table, such as In, Ga, or Al; and an element selected from group VIb of the periodic table, such as O, S, Se, or Te exhibits high energy conversion efficiency and has little influence of optical deterioration. Thus, there are expectations that the thin film solar battery will provide the next-generation solar battery. Particularly, high conversion efficiency is said to be obtainable by using a vapor deposition process called three-stage process.

### CITATION LIST

### Non-Patent Document

### (Non-Patent Document 1)

Non-Patent Document 1: Prog. Photovolt: Res. Appl. (2008), 16:235-239
Non-Patent Document 2: Wide-Gap Chalcopyrites (Springer Series in MATERIALS SCIENCE) p. 146
Non-Patent Document 3: Applied Physics Letters 63 (24)(1993) p. 3294

### SUMMARY OF THE INVENTION

### Problem to be Solved by the Invention

The stoichiometric composition ratio of Cu and the group IIIb element in a chalcopyrite p-type semiconductor using Cu as group Ib is Cu (at %)/group IIIb (at %)=1.0. In the following, Cu (at %)/group IIIb (at %)<1.0 will be referred to as a Cu-poor composition, and Cu (at %)/group IIIb (at %)>1.0 will be referred to as a Cu-rich composition.

In a solar battery using a general Cu-containing chalcopyrite p-type light absorption layer, the light absorption layer is adjusted to the Cu-poor composition in use. This is because if the Cu/IIIb element ratio of the light absorption layer exceeds the stoichiometric composition ratio and enters the Cu-rich composition, a compound (CuₓVIb) between Cu and the group VIb element will be deposited as a heterogenous phase. Because the CuₓVIb is a high conductivity material, if the heterogenous phase is present in the light absorption layer, the back electrode layer and the buffer layer or the window layer may become short-circuited, greatly deteriorating the solar battery characteristics. Accordingly, the chalcopyrite p-type semiconductor film of the Cu-rich composition has not been generally used as a light absorption layer.

On the other hand, the chalcopyrite p-type semiconductor film having the Cu-rich composition is reported to have small defect density compared with the film of the Cu-poor composition (Non-Patent Document 2). When a p-type semiconductor film with small defect density is used in the light absorption layer of a solar battery, it is believed that high conversion efficiency can be obtained because the transport characteristics of the light generating carrier are high. However, as described above, the chalcopyrite p-type semiconductor film having the Cu-rich composition simultaneously has the heterogenous phase of CuₓVIb, so that the inherently good carrier transport characteristics of the Cu-rich composition film cannot be fully taken advantage of

In order to solve the problem, an attempt has been made to selectively remove the heterogenous phase of CuₓVIb (Non-Patent Document 3). This is a technology whereby the p-type semiconductor film having the heterogenous phase is immersed in a potassium cyanide (KCN) aqueous solution so as to selectively remove only the heterogenous phase (hereafter referred to as “KCN etching”). However, in the solar battery using the KCN-etched light absorption layer, i.e., the light absorption layer from which the heterogenous phase of conductive CuₓVIb is removed, although an improvement in characteristics can be made compared with those prior to etching, sufficient conversion efficiency expected from the inherently good carrier transport characteristics of the Cu-rich composition film has not been obtained.

The purpose of the present invention is to provide a compound semiconductor solar battery having high photoelectric conversion efficiency.

### Solution to the Problem

In order to achieve the purpose, a compound semiconductor solar battery according to the present invention includes a back electrode layer; a light absorption layer; and a transparent electrode layer. The light absorption layer is a p-type semiconductor layer including Cu, Ga, and an element selected from group VIb elements. In a photoluminescence spectrum measurement or a cathode luminescence spectrum measurement of the light absorption layer, an emission spectrum includes a peak with a half-value width of not less than 1 meV and not more than 15 meV. A ratio of particles with the grain size of not less than 2 μm and not more than 8 μm in a surface of the light absorption layer to the surface of the light absorption layer is not less than 90%.

According to the compound semiconductor solar battery of the present invention, a higher photoelectric conversion efficiency than the conventional compound semiconductor solar battery can be obtained.

The p-type semiconductor layer having the half-value width of the emission peak of not less than 1 meV and not more than 15 meV in a photoluminescence spectrum measurement or a cathode luminescence spectrum measurement makes it possible to obtain a light absorption layer with excellent carrier transport characteristics. The photoluminescence spectrum and the cathode luminescence spectrum strongly depend on the energy level state of the semiconductor material. Thus, it is surmised that, when the p-type semiconductor film in which the photoluminescence or cathode luminescence with a narrow half-value width is used in the light absorption layer, the energy level fluctuation in the light absorption layer is decreased, whereby the carrier recombination probability is decreased. In addition, it is surmised that the higher photoelectric conversion efficiency than the conventional technology is obtained by a decrease in light generating carrier recombination at the grain boundary when the ratio of the particles with the grain size of not less than 2 μm and not more than 8 μm in the light absorption layer surface to the surface is not less than 90%.

It is believed that when the grain size is not less than 2 μm, the grain boundary is decreased, the amount of a heterogenous phase present along the grain boundary is decreased, and the shunt resistance can be increased. It is also believed that when the grain size is not more than 8 μm, a proper amount of grain boundary can be ensured, whereby deterioration of carrier transport characteristics can be prevented.

Preferably, the light absorption layer is a p-type semiconductor layer further including In. By adjusting the ratio of In and Ga, the band gap energy of the light absorption layer can be changed between 1.0 eV and 2.5 eV. In this way, the spectral sensitivity characteristics of the p-type semiconductor layer can be adjusted to the spectrum of the incident light source as needed, such as sunlight.

Preferably, the light absorption layer has a cross sectional structure including a column-shaped portion in which only a single particle is present in a film thickness direction, the portion having a cross-sectional area of which a ratio to a cross-sectional area of the entire film is not less than 90%. In this way, deterioration of carrier transport characteristics due to excessive amount of grain boundary in the film thickness direction can be prevented, whereby even higher photoelectric conversion efficiency can be obtained.

Further preferably, the composition ratio of Cu and the group IIIb element in the light absorption layer is not less than 0.99 and not more than 1.01. When not less than 0.99, a film with excellent carrier transport characteristics can be obtained, whereby even higher conversion efficiency can be obtained. When not more than 1.01, the amount of the heterogenous phase of CuₓVIb can be made such that the shunt resistance of the solar battery is not influenced, whereby higher conversion efficiency can be obtained.

Further preferably, the light absorption layer has a carrier density of not less than 1×10¹⁶ cm⁻³ and not more than 5×10¹⁶ cm⁻³. When not less than 1×10¹⁶ cm⁻³ cm, the diffusion potential is increased, whereby a high open voltage can be obtained and higher conversion efficiency can be obtained. When not more than 5×10¹⁶ cm⁻³ cm, a proper depletion layer width can be obtained, whereby a decrease in short-circuit current can be prevented and higher conversion efficiency can be obtained.

### Effects of the Invention

According to the present invention, a compound semiconductor solar battery with high conversion efficiency can be provided.

### BRIEF DESCRIPTION OF THE DRAWINGS

FIG. 1 is a schematic cross sectional view of a solar battery according to an embodiment of the present invention.

FIG. 2 is a schematic view of a particle shape (particle shape parameter B) in a cross section of a light absorption layer.

FIG. 3 illustrates SEM image photographed portions on a 10 cm×10 cm substrate for grain size distribution computation.

FIG. 4 is a surface SEM image of the light absorption layer used in the solar battery according to example 21.

FIG. 5 is a cross section SEM image of the light absorption layer used in the solar battery according to example 21.

### MODE FOR CARRYING OUT THE INVENTION

In the following, a preferred embodiment of the present invention will be described with reference to the drawings. Throughout the drawings, similar or equivalent elements will be designated with similar signs. The up-down and left-right positional relationships are as illustrated in the drawings. Redundant descriptions may be omitted.

### (Compound Semiconductor Solar Battery)

FIG. 1 illustrates a compound semiconductor solar battery 2 according to the present embodiment.

The compound semiconductor solar battery 2 is a thin film solar battery including a substrate 6, a back electrode layer 8 disposed on the substrate 6, a light absorption layer 10 as a p-type semiconductor layer formed on the back electrode layer 8, a buffer layer 14 formed on the light absorption layer 10, a semi-insulating layer 16 formed on the buffer layer 14, a window layer 18 (transparent conductive layer) formed on the semi-insulating layer 16, and an upper electrode 20 (lead electrode) formed on the window layer 18. In the following, the compound semiconductor solar battery may be referred to as a solar battery.

For the substrate 6, a glass substrate of soda lime glass (blue sheet glass), white glass (white sheet glass), or alkaline-free glass and the like may be used. Alternatively, a metal foil or plate of stainless steel, aluminum, or titanium and the like may be used. A plastic film, such as a PET film, a PEN film, or a polyimide film may also be used.

For the back electrode layer 8, a metal such as Mo, W, Ti, Cr, Nb, V, or Mn is used.

When Mo is used for the back electrode layer 8, reaction of the back electrode layer 8 with the other layers can be suppressed, whereby deterioration of conversion efficiency can be prevented. Further, because the sheet resistance value of Mo is relatively low compared with the other listed metals, the series resistance of the solar battery can be lowered, thus tending to provide good conversion efficiency.

The light absorption layer 10 is a p-type compound semiconductor layer including Cu, Ga, and at least one type of element selected from group VIb elements. At the position of Ga, In may be added.

The photoluminescence spectrum or cathode luminescence spectrum of the light absorption layer 10 includes an emission peak of which the half-value width is not less than 1 meV and not more than 15 meV. This emission spectrum is observed at low temperature of not more than 10K (Kelvin).

When the half-value width of the photoluminescence spectrum or cathode luminescence spectrum obtained from the light absorption layer 10 is greater than 15 meV, the carrier transport characteristics of the p-type light absorption layer tend to be deteriorated, making it difficult to obtain high conversion efficiency.

When the half-value width of the photoluminescence spectrum or cathode luminescence spectrum obtained from the light absorption layer 10 is smaller than 1 meV, identification from noise tends to become difficult, making the detection difficult.

On a surface of the light absorption layer 10, the ratio of particles with the grain size of not less than 2 μm and not more than 8 μm in the light absorption layer 10 to the surface of the light absorption layer (hereafter referred to as “particle shape parameter A”) is not less than 90%. When the particle shape parameter A is not less than 90%, recombination of light generating carrier at a grain boundary can be decreased, whereby high conversion efficiency can be obtained. When the grain size is not less than 2 μm, the grain boundary is decreased and the residual amount of the heterogenous phase of CuₓVIb that is present along the grain boundary is decreased, whereby shunt resistance is increased and high conversion efficiency can be obtained. When the grain size is not more than 8 μm, the stress in film can be more readily reduced, thus making it more difficult for film peeling to occur and ensuring a proper amount of grain boundary such that good carrier transport characteristics can be obtained.

Here, the “surface” refers to a surface of the light absorption layer 10 on the opposite side from the surface contacting the back electrode layer 8. Namely, the surface refers to the side of the light absorption layer 10 on which light is incident. In FIG. 1, the surface is the one on the side contacting the buffer layer 14.

Preferably, a cross sectional structure of the light absorption layer 10 includes a column-shaped portion in which only a single particle is present in a film thickness direction, the portion having a cross-sectional area ratio (hereafter referred to as “particle shape parameter B”) of not less than 90% with respect to a cross-sectional area of the entire film. In this way, the amount of grain boundary in the film thickness direction can be decreased, whereby good carrier transport characteristics tend to be obtained, making it possible to obtain high conversion efficiency.

The “cross-sectional area” herein refers to the area of a mechanically cut surface of the light absorption layer 10 that has been polished and planarized, or a cross sectional surface of the light absorption layer 10 exposed in the film thickness direction by focused ion beam (FIB) process.

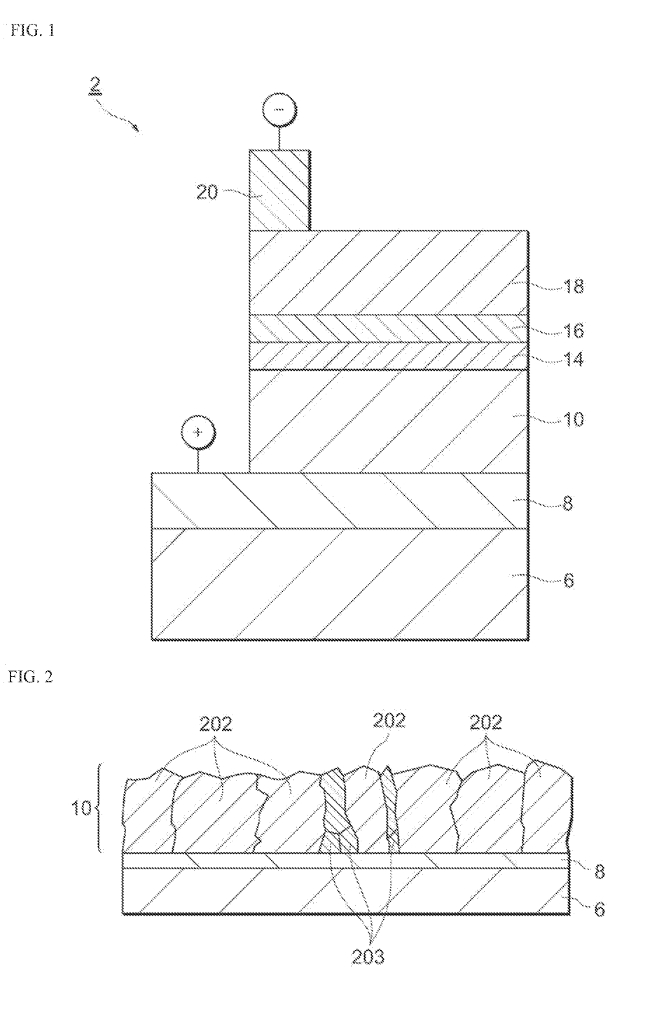

FIG. 2 is a schematic view of the particle shape (particle shape parameter B) of the light absorption layer cross section. FIG. 2 is a cross section of the light absorption layer 10 exposed by planarization. In column-shaped portions 202, only a single particle is present in the film thickness direction. In portions 203, a plurality of particles is present in the film thickness direction. The particle shape parameter B is computed according to expression (1).

Particle shape parameter B=area of 202/(area of 202+area of 203)×100 (1)

Preferably, the composition ratio of Cu and the group IIIb element (Cu/group IIIb composition ratio) in the light absorption layer 10 is not less than 0.99 and not more than 1.01. When the Cu/group IIIb composition ratio is smaller than 1.01, the deposited amount of the heterogenous phase of the conductive CuₓVIb is not such that the shunt resistance of the solar battery is influenced, thus tending to increase conversion efficiency. When the ratio is greater than 0.99, the above-described energy level fluctuation is decreased, whereby high conversion efficiency tends to be obtained.

Preferably, when excitation light dependency is measured in photoluminescence measurement with respect to the light absorption layer 10, the relationship between the excitation light intensity Iₑₓ^{k} and the photoluminescence intensity I_{PL} is expressed by expression (2):

I_{PL}∝Iₑₓ^{k} (2)

where 1<k<2. In this way, high conversion efficiency tends to be obtained.

Preferably, the carrier density of the light absorption layer 10 is not less than 1×10¹⁶ cm⁻³ and not more than 5×10¹⁶ cm⁻³. When not less than 1×10¹⁶ cm⁻³, the diffusion potential can be increased, whereby high open voltage can be obtained, thus tending to increase conversion efficiency even more. When not more than 5×10¹⁶ cm⁻³ cm, a proper width of the depletion layer can be obtained, whereby a decrease in short-circuit current can be prevented and high conversion efficiency tends to be obtained.

Preferably, the light absorption layer 10 has a film thickness of between 1 μm and 5 μm. When not less than 1 μm, the incident light can be effectively absorbed, whereby high conversion efficiency tends to be obtained. When not more than 5 adhesion between the light absorption layer 10 and the other layers is increased, whereby film peeling is less likely to occur and the manufacturing yield can be increased. Further, the series resistance can be decreased, whereby high conversion efficiency tends to be obtained.

For the buffer layer 14, material such as CdS, ZnS, ZnSe, InS, InSe, ZnSSe, Zn(S, OH), ZnSO, ZnSeO, or ZnSSeO is used.

Preferably, the buffer layer 14 has a thickness in the range of not less than 0.01 μm and not more than 0.1 μm. When not less than 0.01 μm, the shunt resistance of the compound semiconductor solar battery 2 can be increased, whereby high conversion efficiency tends to be obtained. When not more than 0.1 μm, optical absorption loss in the buffer layer 14 can be suppressed, whereby high conversion efficiency tends to be obtained.

The buffer layer 14 may not necessarily be provided; however, when provided, high conversion efficiency tends to be obtained.

For the semi-insulating layer 16, i-ZnO (undoped ZnO), ZnMgO, or the like may be used.

Preferably, the semi-insulating layer 16 has a thickness in the range of not less than 0.01 μm and not more than 0.1 μm. When not less than 0.01 μm, the shunt resistance of the solar battery can be increased, whereby high conversion efficiency tends to be obtained. When not more than 0.1 μm, an increase in the series resistance of the solar battery can be suppressed, whereby high conversion efficiency tends to be obtained.

The semi-insulating layer 16 may not necessarily be provided; however, when provided, high conversion efficiency tends to be obtained.

For the window layer 18, a transparent conductive film of ZnO, ITO, SnO2, ZnInO or the like to which a group IIIb element such as Al, B, or Ga is added is used.

For the upper electrode 20, material such as Al, Cu, Au, Ag, C, Pt, or Ni is used for current collection.

The upper electrode 20 may not necessarily be provided; however, when provided, high conversion efficiency tends to be obtained.

### (Compound Semiconductor Solar Battery Manufacturing Method)

According to the present embodiment, the back electrode layer 8 is formed on the substrate 6 by, e.g., sputtering, electronic beam vapor deposition, or printing.

When formed by sputtering, the back electrode layer 8 with low resistance can be uniformly formed in a relatively large area, whereby in-plane solar battery characteristics variations can be decreased and high conversion efficiency tends to be obtained.

The formation of the light absorption layer 10 is performed after the back electrode layer 8 is formed.

A method of forming the light absorption layer 10 involves a two-stage vapor deposition process including a step of simultaneous vacuum vapor deposition of a group IIIb element including Ga and a group VIb element, and a step of simultaneous vacuum vapor deposition of Cu and a group VIb element. The method sequence may be started from either of the two steps. The steps may be repeated as long as the number of the stages is two or more. By using a multi-stage vapor deposition process, localized excessive deposition of the heterogenous phase of CuₓVIb can be suppressed, whereby CuₓVIb can be deposited relatively uniformly on the light absorption layer 10 surface. In this way, the grain size can be readily controlled in the aforementioned range, whereby high conversion efficiency tends to be obtained.

In another method that may be used for forming the light absorption layer 10, an alloy or sintered body target comprising a group IIIb element including Ga and a group VIb element, and an alloy or sintered body target comprising Cu and a group VIb element are respectively sequentially sputtered, obtaining two layers of precursor layers, which are then subjected to heat treatment in a mixture gas of Ar to which H₂Se or H₂S is added (referred to as “two layer sputtering+selenization heat treatment” or “two layer sputtering+sulfurization heat treatment)). Instead of the alloy or sintered body target comprising Cu and a group VIb element, a Cu metal target may be used. The two layers of precursor layers may be formed not just by sputtering but also by, e.g., electrocrystallization, printing, or vacuum vapor deposition process. The total number of precursor layers is not limited to two and may be greater than two. In this way, localized excessive deposition of the heterogenous phase of CuₓVIb can be suppressed and CuₓVIb can be deposited on the light absorption layer 10 surface relatively uniformly, whereby the grain size can be readily controlled in the aforementioned range and high conversion efficiency can be obtained.

Preferably, the Cu/group IIIb composition ratio immediately after the film formation of the light absorption layer 10 ranges from 1.05 to 1.80. In this way, high conversion efficiency tends to be obtained. When the Cu/group IIIb composition ratio is greater than 1.05, a film with relatively large carrier transport characteristics can be obtained, whereby conversion efficiency tends to be relatively increased. When the Cu/group IIIb composition ratio is smaller than 1.80, the conductive CuₓVIb can be deposited mainly on the film surface while suppressing deposition at the grain boundary in the film In this way, removal of the CuₓVIb in a subsequent step can be facilitated, whereby the shunt resistance of the compound semiconductor solar battery 2 can be increased and the conversion efficiency tends to be increased.

Preferably, the CuₓVIb compound is removed after the light absorption layer 10 is formed. The heterogenous phase of CuₓVIb compound may be removed by various methods, such as etching process (KCN etching) involving immersion in a potassium cyanide aqueous solution, electric chemical etching, or heat treatment in forming gas atmosphere. After the formation of the light absorption layer 10, simultaneous vapor deposition of group IIIb and group VIb may be performed so as to react with and consume excessive CuₓVIb compound, forming a Cu-group IIIb-group VIb compound. By these methods, the conductive CuₓVIb compound can be removed from the light absorption layer 10, whereby the conversion efficiency tends to be increased.

When the buffer layer 14 is formed after the formation of the light absorption layer 10, chemical bath deposition (CBD process), vacuum vapor deposition process, sputtering, or chemical vapor deposition (CVD process) and the like may be used.

When the semi-insulating layer 16 is provided, sputtering, or chemical vapor deposition (CVD process) and the like may be used for formation.

The window layer 18 may be formed by, e.g., sputtering or chemical vapor deposition (CVD process).

The upper electrode 20 is formed by, e.g., sputtering, vacuum vapor deposition process, or printing. An appropriate shape pattern is formed by computing the current collect efficiency from the opening portion area and the resistivity of the window layer 18.

By the above-described procedure, the compound semiconductor solar battery 2 according to the present embodiment is formed.

### EXAMPLES

While the present invention will be described in more concrete terms in the following with reference to Examples and Comparative Examples, the present invention is not limited to the following examples.

### Example 1

After a soda lime glass measuring 10 cm in length×10 cm in width×1 mm in thickness was washed and dried, a film-shaped back electrode layer comprising the simple substance of Mo was formed on the soda lime glass 6 by DC sputtering. The back electrode layer had a film thickness of 1 μm.

The “substrate” refers to a member on which a film is formed or an object that is measured in each step.

A light absorption layer was formed using a physical vapor deposition (PVD) apparatus. Prior to the film formation for the p-type light absorption layer, the relationship between the flux ratio of each material element and the composition in the obtained film was measured beforehand so as to adjust the film composition. The flux of each element was modified as needed by adjusting the temperature of each K cell.

The light absorption layer in Example 1 was formed by the two-stage vapor deposition process. The procedure of the two-stage vapor deposition process will be described below.

After the back electrode layer was formed, the substrate was installed in a chamber of the PVD apparatus, and the chamber was degassed. The pressure in the vacuum apparatus was adjusted to reach 1.0×10⁻⁸ torr.

In the first stage, the substrate was heated to 350° C. After the temperature had stabilized, the shutter of each of the K cells for In, Ga, and Se was opened, vapor-depositing In, Ga, and Se on the substrate. The flux of In and Ga was adjusted before film formation in advance so that a Ga/(In+Ga) ratio of the film composition became approximately 0.5 after film formation. At the point in time of formation of a layer of about 1.5 μm thickness on the substrate by the vapor deposition, the shutter of each of K cells for In and Ga was closed. Supply of Se was continued. Thereafter, in the second stage, the substrate was heated to 540° C. and, after the temperature had stabilized, the shutter of the K cell for Cu was opened, thereby performing vapor deposition of Cu and Se. In the second stage, constant electric power was employed for heating the substrate, and no feedback of temperature value to electric power was implemented. The surface temperature of the substrate was monitored with a radiation thermometer. Three minutes after the point in time when the temperature increase of the substrate had stopped and a temperature decrease had started (hereafter, the time from the point in time of the start of a decrease in temperature and the closing of the K cell for Cu will be referred to as “second stage Cu retention time”), the shutter of the K cell for Cu was closed, ending the vapor deposition of Cu. This method of monitoring the surface temperature of the substrate enables confirmation of the film composition turning Cu-rich during film formation. Thereafter, the substrate was cooled to 200° C. and then the shutter of the K cell for Se was closed, ending the film formation for the light absorption layer.

After the light absorption layer film formation, the compositional amount of each of Cu, In, Ga, and Se in the film was measured using an energy dispersive X-ray spectroscopy (EDX) apparatus attached to a scanning micro electron spectroscopy (SEM) apparatus.

After the composition of the light absorption layer was confirmed, the substrate was immersed in a potassium cyanide aqueous solution (10 wt %) for 3 minutes (KCN etching), removing the heterogenous phase of CuₓSe included in the light absorption layer.

After the heterogenous phase removal process, in order to confirm the film morphology, evaluation was performed by scanning micro electron spectroscopy (SEM). Together with surface observation confirming the grain size based on measurement from the surface, observation of the cross sectional structure was also performed after the substrate was processed by FIB.

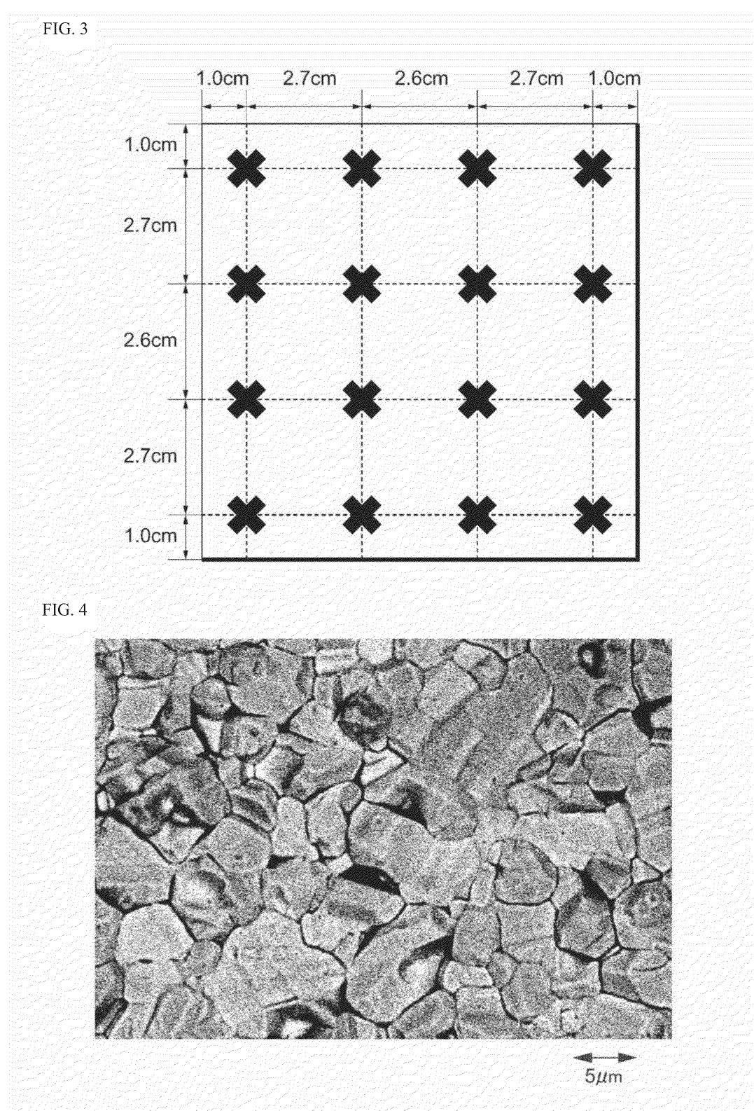

Surface observation was performed to determine the grain size of the light absorption layer surface and its distribution. The light absorption layer surface was photographed at 16 locations in the substrate plane (see FIG. 3) under the condition of the image magnification power of 5000, and a resultant SEM image was analyzed by the free software ImageJ (from the National Institute of Health) to quantitatively analyze the image grain size distribution. As a result of computing an average value of the grain size distribution at each measured location, the ratio of portions with the grain size of not less than 2 μM and not more than 8 μm to the entire surface area (particle shape parameter A) was 93.6%.

Then, the cross sectional structure of the light absorption layer processed by FIB was observed and a grain size evaluation in the film thickness direction was performed. A cross section of the light absorption layer was photographed at the same 16 locations (see FIG. 3) as for surface observation under the condition of the image magnification power of 10000, and a resultant SEM image was analyzed to determine the ratio of the column-shaped portions in which only the single columnar particle was present in the film thickness direction to the cross-sectional area (particle shape parameter B), and an average value of the analysis result at each measured location was computed. The result was 84.5%.

Further, using the energy dispersive X-ray spectroscopy (EDX) apparatus attached within the same apparatus, the compositional amount of each of Cu, In, Ga, and Se was measured. The Cu/(In+Ga) composition ratio in the light absorption layer after heterogenous phase removal was 1.01, confirming that the heterogenous phase had been greatly removed.

After the composition and morphology evaluation of the light absorption layer, a CdS film was formed on the light absorption layer as a buffer layer of 50 nm thickness by chemical bath deposition (CBD) process.

After the formation of the buffer layer, an i-ZnO layer (semi-insulating layer) of 50 nm thickness was formed on the buffer layer. This was followed by the formation on the i-ZnO layer, in the same chamber, of a ZnO layer (window layer) of 0.5 μm thickness to which Al had been added. The i-ZnO layer (semi-insulating layer) and the ZnO layer to which Al had been added were formed by RF sputterring.

After the window layer was formed, photoluminescence measurement of the light absorption layer was performed. As the excitation light source for the measurement, an Ar ion laser having the wavelength of 514.5 nm was used. During measurement, the substrate was cooled down to 10K (Kelvin) in a cryostat. The excitation light intensity was changed from 1 mW/cm² to 100 mW/cm² so as to measure the excitation light intensity dependency of the photoluminescence intensity.

The narrowest half-value width of the emission peak in the photoluminescence spectrum obtained during the measurement at 10 mW/cm² was 9 meV.

When the relationship between the photoluminescence intensity I_{PL} of the narrowest half-value width emission peak and the excitation light intensity Iₑₓ^{k} was expressed by expression (1), the value of k was 1.11.

Further, a part of the substrate was cut, and cathode luminescence measurement of the light absorption layer was performed from the fracture surface. The measurement was performed at 10K (Kelvin) as in the case of photoluminescence. In the cathode luminescence spectrum obtained by the measurement, the narrowest half-value width of emission was 9 meV.

After the formation of the window layer, an upper electrode comprising Ni of 50 nm thickness and Al of 1 μm thickness thereon was formed on the ZnO layer to which Al had been added. The upper electrode was formed by DC sputtering. In this way, the compound semiconductor solar battery according to Example 1 was obtained.

After the formation of the upper electrode, capacitance-voltage (C-V) measurement was performed. The measurement was performed at room temperature, the applied voltage was from −1 V to 1 V, and the frequency was set to 1 MHz. From the values obtained by the measurement, a 1/C2-V plot (Mott-Schotkky plot) was created, and the carrier density of the light absorption layer was computed.

Table 1 shows the material used for the light absorption layer; film formation method; second stage Cu retention time; Cu/(In+Ga) composition ratio and Ga/(In+Ga) composition ratio of the light absorption layer immediately after film formation; Cu/(In+Ga) composition ratio of the light absorption layer after the heterogenous phase removal process; the narrowest half-value width value of emission in the photoluminescence spectrum and the cathode luminescence spectrum of the light absorption layer (which will be respectively referred to in the following as “PL half-value width” and “CL half-value width”); the value of k (k value) in the measurement of the excitation light intensity dependency of the photoluminescence intensity; heterogenous phase removal process method; the particle shape parameter A computed from SEM image observation; the particle shape parameter B; and the carrier density of the light absorption layer.

### Examples 2 to 5

The solar batteries according to Examples 2 to 5 were obtained in the same way as in Example 1 with the exception that during the formation of the light absorption layer, the second stage Cu retention time was set to the time shown in Table 1.

### Comparative Examples 1 and 2

The solar batteries according to Comparative Examples 1 and 2 were obtained in the same way as in Example 1 with the exception that the film formation for the light absorption layer was performed by a single-stage vacuum vapor deposition process. In the following, the single-stage vacuum vapor deposition process will be described.

Prior to film formation, the relationship between the flux ratio of each material element and the compositions included in the obtained film was measured in advance so as to adjust the film composition. The flux ratio for each element was modified as needed by adjusting the temperature of each K cell. In the light absorption layer formation step according to Comparative Example 1, the flux for each element was set such that the Cu/(In+Ga) composition ratio was 1.05 and the Ga/(In+Ga) composition ratio was 0.50 immediately after the film formation. In the light absorption layer formation step according to Comparative Example 2, the flux for each element was set such that the Cu/(In+Ga) composition ratio was 1.35 and the Ga/(In+Ga) composition ratio was 0.50 immediately after the film formation.

The substrate was installed in the chamber of the PVD apparatus, and the chamber was degassed. The pressure reached in the vacuum apparatus was 1.0×10⁻⁸ torr.

Thereafter, the substrate was heated to 540° C. and, after the temperature had stabilized, the shutter of the K cell for each of Cu, In, Ga, and Se was opened, thereby vapor-depositing Cu, In, Ga, and Se on the substrate. At the point in time when a layer of about 2 μm thickness was formed on the substrate by this vapor deposition, the shutter of the K cell for each of Cu, In, Ga was closed. After the substrate was cooled down to 200° C., the shutter of the K cell for Se was closed, ending the film formation for the light absorption layer.

Table 1 shows the solar battery fabrication conditions for Examples 2 to 5 and Comparative Examples 1 and 2 and the results of various measurements.

TABLE 1

| | | | | Cu/(In + Ga) | Ga/(In + Ga) | Cu/(In + Ga) | |
|---|---|---|---|---|---|---|---|
| | | | Second | ratio | ratio | ratio | |
| | | | stage | (Immediately | (Immediately | (After | PL half- |
| | | | Cu | after | after | heterogenous | value |
| | | Film forming | retension | film | film | phase | width |
| | Material | method | time (min) | formation) | formation) | removal) | (meV) |
| Comp. Ex. | Cu(In,Ga)Se₂ | One-stage | — | 1.05 | 0.50 | 1.01 | 15 |
| | | vapor | | | | | |
| | | deposition | | | | | |
| Comp. Ex. | Cu(In,Ga)Se₂ | One-stage | — | 1.35 | 0.50 | 1.01 | 10 |
| | | vapor | | | | | |
| | | deposition | | | | | |
| Ex. 1 | Cu(In,Ga)Se₂ | Two-stage | 3 | 1.10 | 0.50 | 1.01 | 9 |
| | | vapor | | | | | |
| | | deposition | | | | | |
| Ex. 2 | Cu(In,Ga)Se₂ | Two-stage | 5 | 1.25 | 0.50 | 1.02 | 8 |
| | | vapor | | | | | |
| | | deposition | | | | | |
| Ex. 3 | Cu(In,Ga)Se₂ | Two-stage | 10 | 1.38 | 0.50 | 1.02 | 6 |
| | | vapor | | | | | |
| | | deposition | | | | | |
| Ex. 4 | Cu(In,Ga)Se₂ | Two-stage | 15 | 1.55 | 0.50 | 1.03 | 4 |
| | | vapor | | | | | |
| | | deposition | | | | | |
| Ex. 5 | Cu(In,Ga)Se₂ | Two-stage | 20 | 1.80 | 0.50 | 1.04 | 3 |
| | | vapor | | | | | |
| | | deposition | | | | | |

| | | | Heterogenous | | | |
|---|---|---|---|---|---|---|
| | CL half- | | phase | Particle | Particle | |
| | value | | removal | shape | shape | Carrier |
| | width | PL | process | Parameter | Parameter | density |
| | (meV) | k value | method | A (%) | B (%) | cm⁻³ |
| Comp. Ex. | 15 | 1.05 | KCN | 84.6 | 55.4 | 8.0 × 10¹⁵ |
| | | | etching | | | |
| | | | 3 min | | | |
| Comp. Ex. | 10 | 1.25 | KCN | 70.2 | 68.0 | 9.8 × 10¹⁵ |
| | | | etching | | | |
| | | | 3 min | | | |
| Ex. 1 | 9 | 1.11 | KCN | 93.6 | 84.5 | 1.5 × 10¹⁶ |
| | | | etching | | | |
| | | | 3 min | | | |
| Ex. 2 | 8 | 1.19 | KCN | 95.5 | 85.2 | 2.4 × 10¹⁶ |
| | | | etching | | | |
| | | | 3 min | | | |
| Ex. 3 | 6 | 1.30 | KCN | 96.9 | 86.2 | 3.5 × 10¹⁶ |
| | | | etching | | | |
| | | | 3 min | | | |
| Ex. 4 | 4 | 1.50 | KCN | 98.1 | 87.1 | 4.2 × 10¹⁶ |
| | | | etching | | | |
| | | | 3 min | | | |
| Ex. 5 | 3 | 1.65 | KCN | 99.0 | 88.0 | 4.7 × 10¹⁶ |
| | | | etching | | | |
| | | | 3 min | | | |

### Examples 6 to 8

The solar batteries according to Examples 6 to 8 were fabricated in the same way as in Example 1 with the exception that the flux ratios for Ga and In were adjusted in advance such that the Ga/(In+Ga) ratio of the light absorption layer after film formation became approximately 0.51, and that the second stage Cu retention time was set to the time shown in Table 2.

### Comparative Examples 3 to 5

The solar batteries according to Comparative Examples 3 to 5 were fabricated in the same way as in Example 1 with the exception that the flux ratios for Ga and In were adjusted in advance such that the Ga/(In+Ga) ratio of the light absorption layer after film formation became 0.51, that the second stage Cu retention time was adjusted so as to obtain the Cu-poor composition, and that the heterogenous phase removal process was not performed.

### Comparative Examples 6 and 7

The solar batteries according to Comparative Examples 6 and 7 were fabricated in the same way as in Example 1 with the exception that the formation of the light absorption layer was performed by the three-stage vapor deposition process, and that the heterogenous phase removal process was not performed. In the following, the three-stage vapor deposition process will be described.

The flux ratios for Ga and In were adjusted in advance such that the Ga/(In+Ga) ratio in the film composition after film formation became 0.51.

In the first stage, the substrate was heated to 350° C., and the shutter of the K cell for each of In, Ga, and Se was opened, thus vapor-depositing In, Ga, and Se on the substrate. At the point in time when a layer of about 1 μm thickness was formed on the substrate by the vapor deposition, the shutter of each of K cells for In and Ga was closed, ending the vapor deposition of In and Ga. Supply of Se was continued.

In the second stage, after the substrate was heated to 540° C., the shutter of the K cell for Cu was opened, thereby vapor-depositing Cu on the substrate together with Se. In the second stage and the third stage which will be described below, constant electric power was used for heating the substrate, and no feedback of temperature value to electric power was implemented. Further, in the second stage, the surface temperature of the substrate was monitored with a radiation thermometer. After it was confirmed that a temperature increase of the substrate had stopped and a decrease in temperature had started, the shutter of the K cell for Cu was closed five minutes later in the case of Comparative Example 6 and 10 minutes later in the case of Comparative Example 7, ending the vapor deposition of Cu. Supply of Se was continued.

In the third stage, the shutter of each of K cells for In and Ga was again opened, vapor-depositing In, Ga, and Se on the substrate as in the first stage. From the point in time when the third stage vapor deposition had been started, the shutter of the K cell for each of In and Ga was closed 15 minutes later in the case of Comparative Example 6 and 20 minutes later in the case of Comparative Example 7, ending the third stage vapor deposition. Thereafter, after the substrate was cooled to 200 degrees, the shutter of the K cell for Se was closed, ending the film formation for the light absorption layer.

Table 2 shows the solar battery fabrication conditions for Examples 6 to 8 and Comparative Examples 3 to 7, and the results of various measurements.

TABLE 2

| | | | | | | Cu/(In + Ga) | |
|---|---|---|---|---|---|---|---|
| | | | | Cu/(In + Ga) | Ga/(In + Ga) | ratio | |
| | | | Second | ratio | ratio | (After | |
| | | | stage | (Immediately | (Immediately | heterogenous | PL half- |
| | | Film | Cu | after | after | phase | value |
| | | forming | retension | film | film | removal | width |
| | Material | method | time (min) | formation) | formation) | process) | (meV) |
| Comp. Ex. | Cu(In,Ga)Se₂ | Two-stage | — | 0.90 | 0.51 | — | 60 |
| | | vapor | | | | | |
| | | evaporation | | | | | |
| Comp. Ex. | Cu(In,Ga)Se₂ | Two-stage | — | 0.95 | 0.51 | — | 55 |
| | | vapor | | | | | |
| | | evaporation | | | | | |
| Comp. Ex. | Cu(In,Ga)Se₂ | Two-stage | — | 0.97 | 0.51 | — | 40 |
| | | vapor | | | | | |
| | | evaporation | | | | | |
| Comp. Ex. | Cu(In,Ga)Se₂ | Three-stage | 5 | 0.97 | 0.51 | — | 30 |
| | | vapor | | | | | |
| | | evaporation | | | | | |
| Comp. Ex. | Cu(In,Ga)Se₂ | Three-stage | 10 | 0.97 | 0.51 | — | 28 |
| | | vapor | | | | | |
| | | evaporation | | | | | |
| Ex. 6 | Cu(In,Ga)Se₂ | Two-stage | 1.5 | 1.05 | 0.51 | 1.01 | 15 |
| | | vapor | | | | | |
| | | evaporation | | | | | |
| Ex. 7 | Cu(In,Ga)Se₂ | Two-stage | 4 | 1.20 | 0.51 | 1.02 | 6 |
| | | vapor | | | | | |
| | | evaporation | | | | | |
| Ex. 8 | Cu(In,Ga)Se₂ | Two-stage | 15 | 1.55 | 0.51 | 1.04 | 5 |
| | | vapor | | | | | |
| | | evaporation | | | | | |

| | | | Heterogenous | | | |
|---|---|---|---|---|---|---|
| | CL half- | | phase | Particle | Particle | |
| | value | | removal | shape | shape | Carrier |
| | width | PL | process | Parameter | Parameter | density |
| | (meV) | k value | method | A (%) | B (%) | cm⁻³ |
| Comp. Ex. | 60 | 0.88 | None | 66.5 | 48.2 | 3.0 × 10¹⁵ |
| Comp. Ex. | 55 | 0.90 | None | 72.0 | 67.1 | 3.2 × 10¹⁵ |
| Comp. Ex. | 40 | 0.92 | None | 79.4 | 94.5 | 3.4 × 10¹⁵ |
| Comp. Ex. | 30 | 0.94 | None | 92.0 | 88.0 | 4.9 × 10¹⁵ |
| Comp. Ex. | 28 | 0.94 | None | 92.3 | 91.2 | 5.9 × 10¹⁵ |
| Ex. 6 | 15 | 1.05 | KCN | 90.0 | 83.2 | 1.1 × 10¹⁶ |
| | | | etching | | | |
| | | | 3 min | | | |
| Ex. 7 | 6 | 1.20 | KCN | 96.9 | 88.0 | 2.2 × 10¹⁶ |
| | | | etching | | | |
| | | | 3 min | | | |
| Ex. 8 | 5 | 1.40 | KCN | 98.1 | 89.0 | 4.3 × 10¹⁶ |
| | | | etching | | | |
| | | | 3 min | | | |

### Comparative Example 8, Examples 9 to 18

The solar batteries according to Comparative Example 8 and Examples 9 to 18 were fabricated in the same way as in Example 1 with the exception that the flux ratios for Ga and In were adjusted in advance such that the Ga/(In+Ga) ratio immediately after the film formation for the light absorption layer exhibited the values shown in Table 3, and that the second stage Cu retention time was set to the times shown in Table 3.

Table 3 shows the solar battery fabrication conditions for Comparative Example 8 and Examples 9 to 18 and the results of various measurements.

TABLE 3

| | | | | Cu/(In + Ga) | Ga/(In + Ga) | Cu/(In + Ga) | |
|---|---|---|---|---|---|---|---|
| | | | Second | ratio | ratio | ratio | |
| | | | stage | (Immediately | (Immediately | (After | PL half- |
| | | | Cu | after | after | heterogenous | value |
| | | Film forming | retension | film | film | phase | width |
| | Material | method | time (min) | formation) | formation) | removal) | (meV) |
| Comp. Ex. | CuInSe₂ | Two-stage | 12 | 1.40 | 0.00 | 1.03 | 6 |
| | | vapor | | | | | |
| | | evaporation | | | | | |
| Ex. 9 | Cu(In,Ga)Se₂ | Two-stage | 12 | 1.40 | 0.10 | 1.03 | 4 |
| | | vapor | | | | | |
| | | evaporation | | | | | |
| Ex. 10 | Cu(In,Ga)Se₂ | Two-stage | 12 | 1.40 | 0.15 | 1.03 | 4 |
| | | vapor | | | | | |
| | | evaporation | | | | | |
| Ex. 11 | Cu(In,Ga)Se₂ | Two-stage | 12 | 1.40 | 0.20 | 1.03 | 5 |
| | | vapor | | | | | |
| | | evaporation | | | | | |
| Ex. 12 | Cu(In,Ga)Se₂ | Two-stage | 12 | 1.40 | 0.25 | 1.03 | 5 |
| | | vapor | | | | | |
| | | evaporation | | | | | |
| Ex. 13 | Cu(In,Ga)Se₂ | Two-stage | 12 | 1.40 | 0.30 | 1.03 | 5 |
| | | vapor | | | | | |
| | | evaporation | | | | | |
| Ex. 14 | Cu(In,Ga)Se₂ | Two-stage | 12 | 1.40 | 0.40 | 1.03 | 6 |
| | | vapor | | | | | |
| | | evaporation | | | | | |
| Ex. 15 | Cu(In,Ga)Se₂ | Two-stage | 12 | 1.40 | 0.50 | 1.03 | 6 |
| | | vapor | | | | | |
| | | evaporation | | | | | |
| Ex. 16 | Cu(In,Ga)Se₂ | Two-stage | 12 | 1.40 | 0.70 | 1.03 | 8 |
| | | vapor | | | | | |
| | | evaporation | | | | | |
| Ex. 17 | Cu(In,Ga)Se₂ | Two-stage | 12 | 1.40 | 0.90 | 1.03 | 10 |
| | | vapor | | | | | |
| | | evaporation | | | | | |
| Ex. 18 | CuGaSe₂ | Two-stage | 12 | 1.40 | 1.00 | 1.03 | 12 |
| | | vapor | | | | | |
| | | evaporation | | | | | |

| | | | Heterogenous | | | |
|---|---|---|---|---|---|---|
| | CL half- | | phase | Particle | Particle | |
| | value | | removal | shape | shape | Carrier |
| | width | PL | process | Parameter | Parameter | density |
| | (meV) | k value | method | A (%) | B (%) | cm⁻³ |
| Comp. Ex. | 6 | 1.33 | KCN | 95.4 | 95.0 | 2.8 × 10¹⁶ |
| | | | etching | | | |
| | | | 3 min | | | |
| Ex. 9 | 4 | 1.35 | KCN | 94.0 | 98.0 | 2.9 × 10¹⁶ |
| | | | etching | | | |
| | | | 3 min | | | |
| Ex. 10 | 4 | 1.38 | KCN | 95.5 | 97.2 | 3.2 × 10¹⁶ |
| | | | etching | | | |
| | | | 3 min | | | |
| Ex. 11 | 5 | 1.41 | KCN | 97.4 | 94.5 | 3.5 × 10¹⁶ |
| | | | etching | | | |
| | | | 3 min | | | |
| Ex. 12 | 5 | 1.44 | KCN | 96.4 | 93.0 | 3.8 × 10¹⁶ |
| | | | etching | | | |
| | | | 3 min | | | |
| Ex. 13 | 5 | 1.42 | KCN | 95.5 | 96.0 | 4.2 × 10¹⁶ |
| | | | etching | | | |
| | | | 3 min | | | |
| Ex. 14 | 6 | 1.32 | KCN | 98.0 | 99.0 | 4.3 × 10¹⁶ |
| | | | etching | | | |
| | | | 3 min | | | |
| Ex. 15 | 6 | 1.40 | KCN | 96.9 | 89.0 | 4.5 × 10¹⁶ |
| | | | etching | | | |
| | | | 3 min | | | |
| Ex. 16 | 8 | 1.55 | KCN | 98.1 | 85.8 | 4.7 × 10¹⁶ |
| | | | etching | | | |
| | | | 3 min | | | |
| Ex. 17 | 10 | 1.40 | KCN | 92.4 | 83.2 | 3.8 × 10¹⁶ |
| | | | etching | | | |
| | | | 3 min | | | |
| Ex. 18 | 12 | 1.55 | KCN | 91.0 | 80.1 | 3.4 × 10¹⁶ |
| | | | etching | | | |
| | | | 3 min | | | |

### Examples 19 to 23

The solar batteries according to Examples 19 to 23 were fabricated in the same way as in Example 1 with the exception that the flux ratios for Ga and In were adjusted in advance such that the Ga/(In+Ga) ratio immediately after the film formation for the light absorption layer exhibited the values shown in Table 4, and that the heterogenous phase removal process was performed by the method shown in Table 4.

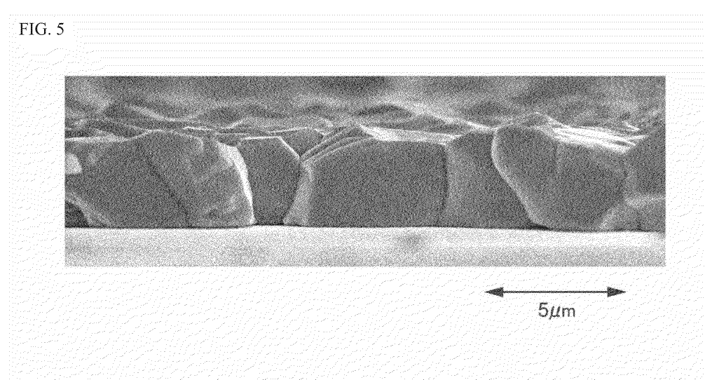

FIG. 4 and FIG. 5 show an SEM surface image and an SEM cross section image of the light absorption layer 10 according to Example 21 used for computing the particle shape parameter A and the particle shape parameter B.

Table 4 shows the solar battery fabrication conditions for Examples 19 to 23 and the results of various measurements.

TABLE 4

| | | | | | | Cu/(In + Ga) | |
|---|---|---|---|---|---|---|---|
| | | | | Cu/(In + Ga) | Ga/(In + Ga) | ratio | |
| | | | Second | ratio | ratio | (After | |
| | | | stage | (Immediately | (Immediately | heterogenous | PL half- |
| | | Film | Cu | after | after | phase | value |
| | | forming | retension | film | film | removal | width |
| | Material | method | time (min) | formation) | formation) | process) | (meV) |
| Ex. 19 | Cu(In,Ga)Se₂ | Two-stage | 15 | 1.56 | 0.41 | 1.03 | 6 |
| | | vapor | | | | | |
| | | evaporation | | | | | |
| Ex. 20 | Cu(In,Ga)Se₂ | Two-stage | 15 | 1.56 | 0.41 | 1.02 | 4 |
| | | vapor | | | | | |
| | | evaporation | | | | | |
| Ex. 21 | Cu(In,Ga)Se₂ | Two-stage | 15 | 1.56 | 0.41 | 1.00 | 5 |
| | | vapor | | | | | |
| | | evaporation | | | | | |
| Ex. 22 | Cu(In,Ga)Se₂ | Two-stage | 15 | 1.56 | 0.41 | 0.99 | 5 |
| | | vapor | | | | | |
| | | evaporation | | | | | |
| Ex. 23 | Cu(In,Ga)Se₂ | Two-stage | 15 | 1.56 | 0.41 | 0.98 | 15 |
| | | vapor | | | | | |
| | | evaporation | | | | | |

| | | | Heterogenous | | | |
|---|---|---|---|---|---|---|
| | CL half- | | phase | Particle | Particle | |
| | value | | removal | shape | shape | Carrier |
| | width | PL | process | Parameter | Parameter | density |
| | (meV) | k value | method | A (%) | B (%) | cm⁻³ |
| Ex. 19 | 6 | 1.35 | KCN | 97.9 | 99.0 | 4.8 × 10¹⁶ |
| | | | etching | | | |
| | | | 3 min | | | |
| Ex. 20 | 4 | 1.35 | KCN | 97.9 | 99.0 | 4.8 × 10¹⁶ |
| | | | etching | | | |
| | | | 5 min | | | |
| Ex. 21 | 5 | 1.35 | KCN | 97.9 | 99.0 | 4.8 × 10¹⁶ |
| | | | etching | | | |
| | | | 10 min | | | |
| Ex. 22 | 5 | 1.35 | KCN | 95.9 | 98.0 | 4.8 × 10¹⁶ |
| | | | etching | | | |
| | | | 20 min | | | |
| Ex. 23 | 15 | 1.01 | KCN | 93.1 | 97.2 | 4.8 × 10¹⁶ |
| | | | etching | | | |
| | | | 60 min | | | |

### Example 24

The solar battery according to Example 24 was obtained in the same way as in Example 1 with the exception that sulfur was used as the group VIb element, that the flux ratios for Ga and In were adjusted in advance such that the Ga/(In+Ga) ratio immediately after the film formation for the semiconductor layer exhibited the values shown in Table 5, and that the second stage Cu retention time was set to the time shown in Table 5.

### Comparative Example 9

The formation of the light absorption layer was performed by the single-stage vapor deposition process. The solar battery according to Comparative Example 9 was obtained in the same way as in Comparative Example 1 with the exception that sulfur was used as the group VIb element, and that the flux for each element ratio was adjusted in advance such that the Cu/(In+Ga) and Ga/(In+Ga) ratios immediately after the film formation for the semiconductor layer exhibited the values shown in Table 5.

Table 5 shows the solar battery fabrication conditions for Example 24 and Comparative Example 9, and the results of various measurements.

TABLE 5

| | | | | | | Cu/(In + Ga) | |
|---|---|---|---|---|---|---|---|
| | | | | Cu/(In + Ga) | Ga/(In + Ga) | ratio | |
| | | | Second | ratio | ratio | (After | |
| | | | stage | (Immediately | (Immediately | heterogenous | PL half- |
| | | | Cu | after | after | phase | value |
| | | Film forming | retension | film | film | removal | width |
| | Material | method | time (min) | formation) | formation) | process) | (meV) |
| Comp. Ex. | Cu(In,Ga)S₂ | One-stage | — | 1.60 | 0.10 | 1.03 | 10 |
| | | vapor | | | | | |
| | | evaporation | | | | | |
| Ex. 24 | Cu(In,Ga)S₂ | Two-stage | 15 | 1.60 | 0.10 | 1.03 | 10 |
| | | vapor | | | | | |
| | | evaporation | | | | | |

| | | | Heterogenous | | | |
|---|---|---|---|---|---|---|
| | CL half- | | phase | Particle | Particle | |
| | value | | removal | shape | shape | Carrier |
| | width | PL | process | Parameter | Parameter | density |
| | (meV) | k value | method | A (%) | B (%) | cm⁻³ |
| Comp. Ex. | 10 | 1.11 | KCN | 65.0 | 60.0 | 8.0 × 10¹⁶ |
| | | | etching | | | |
| | | | 3 min | | | |
| Ex. 24 | 10 | 1.23 | KCN | 90.2 | 75.0 | 5.0 × 10¹⁶ |
| | | | etching | | | |
| | | | 3 min | | | |

### Comparative Example 10

The light absorption layer was formed by DC sputtering followed by heat treatment. The details will be described in the following.

The substrate with the back electrode layer formed thereon was installed in the DC sputtering apparatus, and precursor layer formation was performed by DC sputtering. Thereafter, the substrate was installed in an annealing oven in which the formation of the light absorption layer was performed by heating treatment. In the following, the details of the sputtering step and the subsequent formation of the light absorption layer by heat treatment will be described.

In the sputtering step, while Ar gas was continuously supplied into the chamber, a target comprising a Cu—Ga alloy (Cu 50 at %, Ga 50 at %) and a target comprising In metal were simultaneously sputtered in the chamber, forming a precursor layer comprising a single layer of a Cu—Ga—In alloy on the substrate. In the sputtering step, the substrate temperature was kept at 200° C., and the flow rate of Ar gas was set such that the atmosphere in the chamber was 1 Pa.

In the heat treatment step following the sputtering step, the substrate temperature was set at 550° C. and the precursor layer was heated for one hour in the mixed atmosphere of Ar and H₂Se so as to selenize the precursor layer, forming a light absorption layer with a thickness of 2 μm.

As the heterogenous phase removal process performed after the film formation, the KCN etching was performed for the time shown in Table 6.

The solar battery according to Comparative Example 10 was fabricated by the same method as for Example 1 with the exception of the following.

### Example 25

The light absorption layer was formed by sputtering and subsequent heat treatment. The details will be described below.

The substrate with the back electrode layer formed thereon was installed in the sputtering apparatus, and precursor layer formation was performed by sputtering. Thereafter, the substrate was installed in the annealing oven in which the formation of the light absorption layer was performed by heating treatment. In the following, the details of the light absorption layer formation by sputtering and subsequent heat treatment will be described.

In the sputtering step, while Ar gas was continuously supplied into the chamber, an alloy target comprising In—Ga—Se (In 25 at %, Ga 25 at %, Se 50 at %) was sputtered in the chamber, and then a Cu2Se target was sputtered. By the sputtering step, a precursor layer including an In—Ga—Se alloy layer and a Cu2Se layer that were sequentially stacked was obtained. In the sputtering step, the substrate temperature was set to 200° C., and the flow rate of Ar gas was set such that the atmosphere in the chamber was 1 Pa.

In the heat treatment step following the sputtering step, the substrate temperature was set to 550° C. and the precursor layer was heated for one hour in the mixed atmosphere of Ar and H₂Se so as to selenize the precursor layer, forming a light absorption layer with a thickness of 2 μm.

Table 6 shows the solar battery fabrication conditions for Example 25 and Comparative Example 10, and the results of various measurements.

TABLE 6

| | | | | | | | Cu/(In + Ga) |
|---|---|---|---|---|---|---|---|
| | | | | | | | ratio |
| | | | | | Cu/(In + Ga) | Ga/(In + Ga) | (After |
| | | | | | ratio | ratio | heterogenous |
| | | | | | (After | (After | phase |
| | | Film | | | heat | heat | removal |
| | Material | forming metho [symbol] | Heat proc [symbol] | Precursor | process) | process) | process) |
| Comp. Ex. | Cu(In,Ga)Se₂ | One-layer | Ar + | Cu—In—Ga [symbol] | 1.62 | 0.50 | 1.01 |
| | | sputtering, | H2Se 60 min | | | | |
| | | selenization | | | | | |
| | | heating process | | | | | |
| Ex. 25 | Cu(In,Ga)Se₂ | Two-layer | Ar + | Cu—Ga | 1.62 | 0.50 | 1.01 |
| | | sputtering, | H2Se 60 min | alloy/In | | | |
| | | selenization | | metal | | | |
| | | heating process | | | | | |

| | | | | Heterogenous | | | |
|---|---|---|---|---|---|---|---|
| | PL half- | CL half- | | phase | Particle | Particle | |
| | value | value | | removal | shape | shape | Carrier |
| | width | width | PL | process | Parameter | Parameter | density |
| | (meV) | (meV) | k value | method | A (%) | B (%) | cm⁻³ |
| Comp. Ex. | 14 | 14 | 1.11 | KCN | 68.2 | 51.2 | 6.2 × 10¹⁶ |
| | | | | Etching | | | |
| | | | | 3 min | | | |
| Ex. 25 | 12 | 12 | 1.11 | KCN | 91.1 | 80.3 | 5.0 × 10¹⁶ |
| | | | | Etching | | | |
| | | | | 3 min | | | |

[symbol]

indicates data missing or illegible when filed

### (Evaluation of Solar Battery Characteristics)

The characteristics of the solar batteries according to Examples 1 to 25 and Comparative Examples 1 to 10 were evaluated using a solar simulator (AM 1.5, 100 mW/cm²). The results are shown in Table 7.

TABLE 7

| | Open | Short-circuit | | Conversion |
|---|---|---|---|---|
| | voltage | current density | | efficiency |
| | Voc (V) | Jsc (mA/cm²) | F.F. | (%) |
| Comp. Ex. 1 | 0.690 | 20.2 | 0.445 | 6.2 |
| Comp. Ex. 2 | 0.701 | 19.2 | 0.488 | 6.6 |
| Ex. 1 | 0.720 | 26.0 | 0.675 | 12.6 |
| Ex. 2 | 0.725 | 26.5 | 0.681 | 13.1 |
| Ex. 3 | 0.728 | 26.8 | 0.690 | 13.5 |
| Ex. 4 | 0.735 | 27.0 | 0.695 | 13.8 |
| Ex. 5 | 0.738 | 27.0 | 0.700 | 13.9 |
| Comp. Ex. 3 | 0.687 | 23.0 | 0.550 | 8.7 |
| Comp. Ex. 4 | 0.686 | 23.0 | 0.560 | 8.8 |
| Comp. Ex. 5 | 0.688 | 23.4 | 0.599 | 9.6 |
| Comp. Ex. 6 | 0.690 | 24.0 | 0.605 | 10.0 |
| Comp. Ex. 7 | 0.692 | 24.1 | 0.606 | 10.1 |
| Ex. 6 | 0.702 | 27.0 | 0.690 | 13.1 |
| Ex. 7 | 0.711 | 27.2 | 0.700 | 13.5 |
| Ex. 8 | 0.717 | 27.4 | 0.699 | 13.7 |
| Comp. Ex. 8 | 0.450 | 37.0 | 0.560 | 9.3 |
| Ex. 9 | 0.570 | 36.5 | 0.695 | 14.5 |
| Ex. 10 | 0.599 | 35.7 | 0.691 | 14.8 |
| Ex. 11 | 0.615 | 35.0 | 0.710 | 15.3 |
| Ex. 12 | 0.640 | 34.8 | 0.720 | 16.0 |
| Ex. 13 | 0.666 | 33.9 | 0.730 | 16.5 |
| Ex. 14 | 0.688 | 32.5 | 0.740 | 16.5 |
| Ex. 15 | 0.705 | 26.0 | 0.700 | 12.8 |
| Ex. 16 | 0.730 | 24.0 | 0.650 | 11.4 |
| Ex. 17 | 0.755 | 23.2 | 0.640 | 11.2 |
| Ex. 18 | 0.788 | 22.0 | 0.620 | 10.7 |
| Ex. 19 | 0.688 | 32.6 | 0.739 | 16.6 |
| Ex. 20 | 0.691 | 32.8 | 0.741 | 16.8 |
| Ex. 21 | 0.715 | 33.2 | 0.790 | 18.8 |
| Ex. 22 | 0.710 | 33.0 | 0.788 | 18.5 |
| Ex. 23 | 0.690 | 31.0 | 0.765 | 16.4 |
| Comp. Ex. 9 | 0.555 | 19.0 | 0.555 | 5.9 |
| Ex. 24 | 0.692 | 24.0 | 0.660 | 11.0 |
| Comp. Ex. 10 | 0.654 | 17.2 | 0.444 | 5.0 |
| Ex. 25 | 0.734 | 22.9 | 0.660 | 11.1 |

It was confirmed that the solar batteries according to Examples 1 to 25 provided with the light absorption layer where the half-value width of the photoluminescence spectrum or cathode luminescence spectrum was not less than 1 meV and not more than 15 meV, and where the ratio of the particles with the grain size of not less than 2 μm and not more than 8 in the surface of the light absorption layer to the surface area of the entire film (particle shape parameter A) was not less than 90% had higher conversion efficiencies than those of the solar batteries according to the Comparative Examples.

It was confirmed that, when compared by the same light absorption layer material, such as Cu (In, Ga) Se₂, the solar batteries according to Comparative Examples 1 and 2 provided with the light absorption layer where, although the half-value width of the photoluminescence spectrum or cathode luminescence spectrum was not less than 1 meV and not more than 15 meV, the particle shape parameter A was less than 90%, had low conversion efficiencies compared with Examples 1 to 5. This tendency was also confirmed from Example 25 and Comparative Example 10 where the light absorption layer was formed by sputtering and heat treatment.

The same was also confirmed from Example 24 and Comparative Example 9 when compared by Cu (In, Ga)S₂.

When compared by the same light absorption layer material, such as Cu (In, Ga) Se₂, it was confirmed that Comparative Examples 3 to 5 provided with the light absorption layer where the half-value width of the photoluminescence spectrum or cathode luminescence spectrum was greater than 15 meV and where the particle shape parameter A was less than 90% had lower conversion efficiencies than the solar batteries according to Examples 6 to 8.

When compared by the same light absorption layer material, such as Cu (In, Ga) Seₑ, it was confirmed that Comparative Examples 6 and 7 provided with the light absorption layer where the half-value width of the photoluminescence spectrum or cathode luminescence spectrum was greater than 15 meV and where the particle shape parameter A was not less than 90% had lower conversion efficiencies than the solar batteries according to Examples 6 to 8.

It was confirmed that the solar battery according to Comparative Example 8 without Ga had lower conversion efficiency than the solar batteries according to Examples 1 to 25 with Ga.

It was confirmed that in the solar batteries where the half-value width of the photoluminescence spectrum or cathode luminescence spectrum was not less than 1 meV and not more than 15 meV and where the particle shape parameter A was not less than 90%, the solar batteries according to Examples 9 to 14 including the column-shaped portion in which only a single particle is present in the film thickness direction with the ratio of a cross-sectional area of the portion to the cross-sectional area of the entire film (crystal shape parameter B) being not less than 90% had higher conversion efficiencies than the solar batteries according to Examples 15 to 18 where the crystal shape parameter B was less than 90%.

It was confirmed that the conversion efficiency of the solar batteries according to Examples 21 and 22 provided with the light absorption layer where the Cu/(In+Ga) ratio was not less than 0.99 and not more than 1.01 had higher conversion efficiencies than the solar batteries according to Examples 19, 20, and 23 provided with the same compositions and requirements as Examples 21 and 22 and where the Cu/(In+Ga) ratio was outside the range of not less than 0.99 and not more than 1.01.

It was confirmed that the conversion efficiency of the solar battery of Example 25 provided with the light absorption layer comprising Cu (In, Ga) Se₂ formed by subjecting the two layers of precursors formed by sputtering to selenization heat treatment, where the half-value width in the photoluminescence spectrum or cathode luminescence spectrum was not less than 1 meV and not more than 15 meV, and where the particle shape parameter A was not less than 90% was higher than the conversion efficiency of the solar battery according to Comparative Example 10 provided with the light absorption layer comprising Cu (In, Ga) Se₂ formed by subjecting one layer of precursor formed by sputtering to selenization heat treatment, where the half-value width of the photoluminescence spectrum or cathode luminescence spectrum was not less than 1 meV and not more than 15 meV and where the particle shape parameter A was less than 90%.

### DESCRIPTION OF REFERENCE SIGNS

2 Solar battery according to embodiment of the present invention
6 Soda lime glass
8 Back electrode layer
10 Light absorption layer
14 Buffer layer
16 Semi-insulating layer
18 Window layer (transparent conductive layer)
20 Upper electrode
24 Cross sectional SEM observed locations on solar battery
202 Column-shaped portion in which only single particle is present in film thickness direction
203 Portion in which a plurality of particles is present in film thickness direction

1. A compound semiconductor solar battery comprising:
a back electrode layer;
a light absorption layer; and
a transparent electrode layer,
wherein:
the light absorption layer is a p-type semiconductor layer including Cu, Ga, and an element selected from group VIb elements;
in a photoluminescence spectrum measurement or a cathode luminescence spectrum measurement of the light absorption layer, an emission spectrum includes a peak with a half-value width of not less than 1 meV and not more than 15 meV; and
a ratio of particles with the grain size of not less than 2 μm and not more than 8 μm in a surface of the light absorption layer to the surface of the light absorption layer is not less than 90%.

2. The compound semiconductor solar battery according to claim 1, wherein the light absorption layer is a p-type semiconductor layer further including In.

3. The compound semiconductor solar battery according to claim 1, wherein:
the light absorption layer has a cross sectional structure including a column-shaped portion in which only a single particle is present in a film thickness direction; and
the portion has a cross-sectional area of which a ratio to a cross-sectional area of the entire film is not less than 90%.

4. The compound semiconductor solar battery according to claim 1, wherein the light absorption layer has a composition ratio of Cu and a group IIIb element of not less than 0.99 and not more than 1.01.

5. The compound semiconductor solar battery according to claim 1, wherein:
the half-value width of photoluminescence of the light absorption layer is the half-value width of photoluminescence measured using an Ar ion laser with a wavelength of 514.5 nm as an excitation light source and at a temperature of 10K (Kelvin).

6. The compound semiconductor solar battery according to claim 1, wherein the light absorption layer has a carrier density of not less than 1×10¹⁶ cm⁻³ and not more than 5×10¹⁶ cm⁻³.

7. A method of manufacturing a light absorption layer of a compound semiconductor solar battery, the method comprising:
a first step of performing simultaneous vacuum vapor deposition of at least a group IIIb element including Ga and a group VIb element; and
a second step of performing simultaneous vacuum vapor deposition of Cu and a group VIb element.

8. A method of manufacturing a light absorption layer of a compound semiconductor solar battery, the method comprising:
a third step of performing sputtering using an alloy or a sintered body target comprising at least a group IIIb element including Ga and a group VIb element;
a fourth step of performing, after the third step, sputtering using an alloy or a sintered body target comprising Cu and a group VIb element; and
a fifth step of performing heat treatment of a precursor layer formed in the third step and the fourth step in a mixture gas of Ar and H₂Se or H₂S.

9. The method of manufacturing a light absorption layer of a compound semiconductor solar battery according to claim 7, wherein:
a Cu/group IIIb composition ratio immediately after film formation is 1.05 to 1.80.
